(19) United States
(12) Patent Application Publication
(10) Pub. No.: US 2026/0187796 A1
(43) Pub. Date: Jul. 2, 2026

(54) DIAGNOSIS SYSTEM AND METHOD BASED ON DEEP LEARNING

(71) Applicant: Samsung Electronics Co., Ltd., Suwon-si (KR)

(72) Inventors: Geunho Yu, Suwon-si (KR); Jinwook Lee, Suwon-si (KR); Jonghun Lee, Suwon-si (KR); Sewon Im, Suwon-si (KR)

(21) Appl. No.: 19/433,237

(22) Filed: Dec. 26, 2025

(30) Foreign Application Priority Data
Jan. 2, 2025 (KR) 10-2025-0000462

(51) Int. Cl. G06T 7/00; G06T 7/11

(52) U.S. Cl. CPC G06T 7/0012; G06T 7/11

(57) ABSTRACT

A diagnosis method includes obtaining video data captured while a transport device of an overhead hoist transport (OHT) moves along a rail, processing the video data to generate training data, training a deep learning-based diagnosis model based on the training data, and obtaining inference results that the deep learning-based diagnosis model inferred a state of the rail based on the video data.

### CROSS-REFERENCE TO RELATED APPLICATION

This application claims priority under 35 U.S.C. § 119 to Korean Patent Application No. 10-2025-0000462, filed on Jan. 2, 2025, in the Korean Intellectual Property Office, the entirety of which is incorporated herein by reference.

### BACKGROUND

An overhead hoist transport (OHT) device is a transport container return device that transports product transport containers, that is, return materials (front opening shipping box (FOSB), multiple application carrier (MAC), cassette (CST), etc.), between facilities within a semiconductor line. An OHT device includes a transport device that moves along a rail installed on the ceiling and transports an object, and a rail for guiding the movement of the transport device.

Since parts of the rail are continuously damaged by vibrations generated while the transport device is moving, inspection of the rail may be necessary. Inspection of a rail may be performed by working from above, with a worker moving a rolling tower to the rail.

### SUMMARY

Some aspects of the present disclosure provide a diagnosis systems and diagnosis methods that reduce the risk and the time elapsed for inspection of equipment (e.g., a rail) and increase the convenience and the reliability of the inspection.

Various other advantages and improvement provided herein will be understood by one of ordinary skill in the art from the following descriptions.

According to some implementations of the present disclosure, there is provided a diagnosis method including obtaining video data captured while a transport device of an overhead hoist transport (OHT) moves along a rail, processing the video data to generate training data, training a deep learning-based diagnosis model based on the training data, and obtaining inference results that the diagnosis model inferred a state of the rail based on the video data.

According to some implementations of the present disclosure, there is provided a diagnosis system including a controller configured to store video data captured while a transport device of an overhead hoist transport (OHT) moves along a rail, a training data generation server configured to obtain first video data from among the video data from the controller and generate training data, a cloud storage configured to store the training data generated by the training data generation server, a model training server configured to train a deep learning-based diagnosis model based on the training data, and a diagnosis server configured to infer a status of the rail based on the diagnosis model.

According to some implementations of the present disclosure, there is provided a diagnosis method including obtaining video data captured while a camera moves along a rail of an overhead hoist transport (OHT) device, extracting first video data from the video data as first image data at a pre-set frames-per-second (FPS) value, extracting augmented image data by performing augmentation on the first image data, training a deep learning-based diagnosis model based on the augmented image data, extracting second video data from the video data as second image data at a pre-set FPS value, obtaining an inference result that the diagnosis model inferred whether the rail is abnormal based on the second image data, and clustering the second image data and determining a diagnosis result for each cluster of the second image data, wherein the diagnosis model is based on at least one of an object detection algorithm and an image segmentation algorithm.

### BRIEF DESCRIPTION OF THE DRAWINGS

FIG. 1 is a schematic flowchart of an example of a diagnosis method;

FIG. 2 is a schematic view of an example of an overhead hoist transport (OHT) device;

FIG. 3 is a flowchart illustrating an example of an operation of generating training data;

FIG. 4 is a block diagram illustrating an example of an operation of obtaining an inference result;

FIG. 5 is a schematic flowchart of an example of a diagnosis method;

FIG. 6 is a block diagram illustrating an example of an operation of determining a diagnosis result;

FIG. 7 is a block diagram illustrating an example of a diagnosis system;

FIGS. 8A and 8B are graphs showing the performance of a diagnosis model;

FIG. 9 is a graph showing the performance of a diagnosis model; and

FIGS. 10A and 10B are graphs illustrating the effect of augmenting training data.

### DETAILED DESCRIPTION

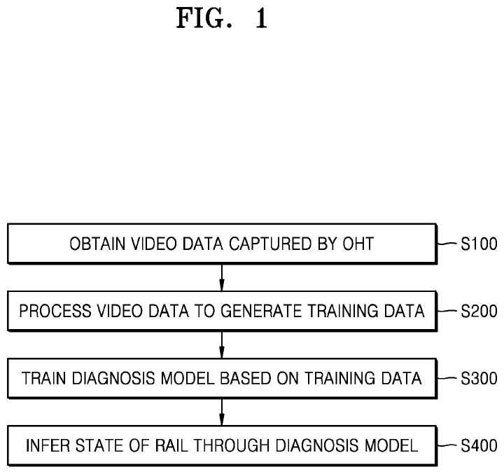

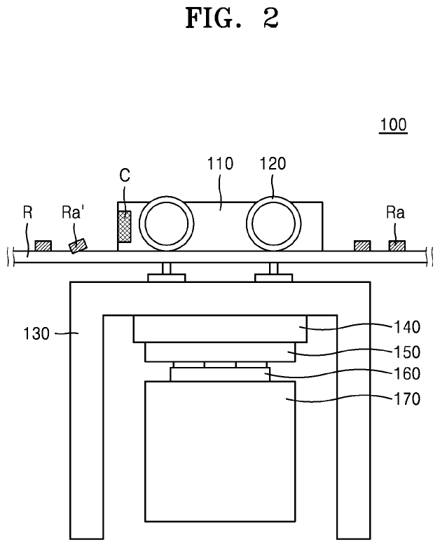

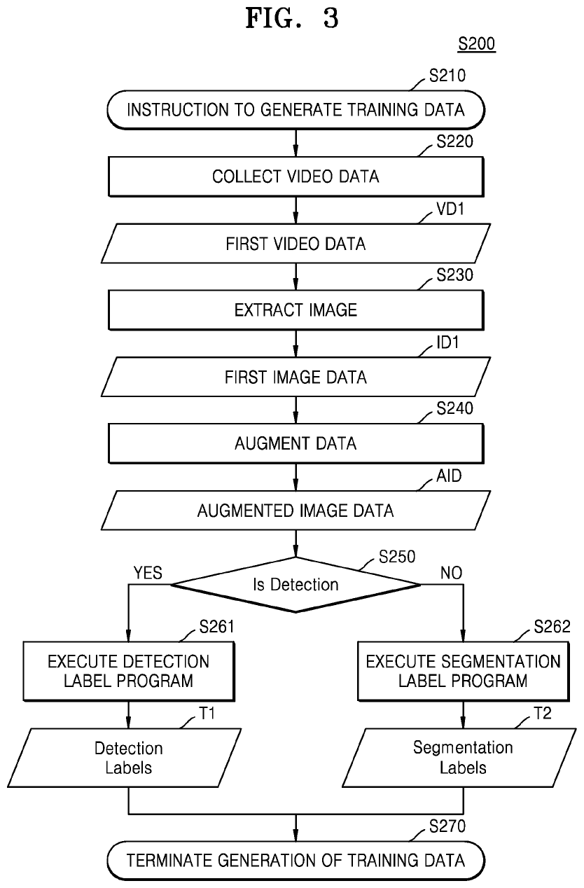

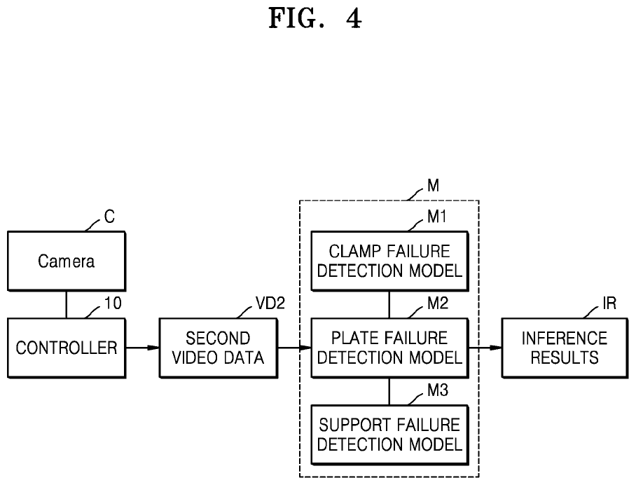

FIG. 1 is a schematic flowchart illustrating an example of a diagnosis method, and FIG. 2 is a schematic view of an example of an overhead hoist transport (OHT) device or OHT system, e.g., an OHT usable for the diagnosis method. FIG. 3 is a flowchart illustrating an example of an operation of generating training data, and FIG. 4 is a block diagram illustrating an example of an operation of obtaining an inference result. The operations of FIGS. 3-4 can be included in diagnosis methods described herein, e.g., the diagnosis method of FIG. 1.

Referring to FIG. 1, a diagnosis method may include operation S100 of obtaining video data captured by the OHT device, operation S200 of processing the video data to generate training data, operation S300 of training a diagnosis model based on the training data, and operation S400 of inferring a state of a rail through the diagnosis model.

Referring to FIGS. 1 and 2 together, the OHT device includes a transport device 100 and a rail R, and video data captured by the OHT device may refer to video data captured while the transport device 100 of the OHT device moves along, or is on, the rail R. According to some implementations, the transport device 100 of the OHT device may include a camera C facing in a direction in which the OHT device travels and/or in a direction opposite to the direction in which the OHT device travels. In some implementations, a camera C may be positioned to face a lateral side of the transport device 100 rather than, or in addition to, in the direction in which the OHT device travels or in the direction opposite to the direction in which the OHT device travels.

In some implementations, the camera C is positioned above the rail R, and video data captured by the camera C may include an image of the upper portion of the rail R. According to some implementations, the camera C may be placed in an area (e.g., a housing 130) of the transport device 100 located at the bottom of the rail R, and thus the video data may include an image of the bottom of the rail R.

Referring to FIG. 2, the rail R of the OHT device may include a plurality of components Ra. The plurality of components Ra may include clamps and/or plates. The OHT device may include a support that secures the rail R to a factory structure, and a clamp may be a member that connects the rail R to the support. A plate may be a member that reinforces a connecting portion or structural support point of the rail R or connects supports to each other.

At least some of the plurality of components Ra may become defective due to reasons such as vibrations that occur as the transport device 100 moves along the rail R. For example, from among the plurality of components Ra, the clamp may lie back, fall down, or flip over as compared to a normal state or may fall off from a normal position and be present on the rail R on which the transport device 100 moves. A plate may be combined with a support via bolts, and a defect may occur in the plate, e.g., separation of a bolt connection. In this way, the rail R of the OHT device may include a defective component Ra′ from among the plurality of components Ra.

A diagnosis method and system in some implementations may infer and/or diagnose the state of a rail to detect the defective component Ra′ through video data of the rail R. In this specification, the components Ra of the rail R to be detected by the diagnosis method and the diagnosis system are described with a focus on the clamp and the plate, but analyzed components are not limited thereto. For example, the diagnosis method and diagnosis system in some implementations may be applied to detect defects in all components that are positioned adjacent to or associated with a rail, such as a support, and/or the rail itself, and that may be photographed by the camera C. As used herein, except where indicated or suggested otherwise, processes performed on a “rail” (such as capturing video/images of a rail, determining a state of a rail, etc.) include processes perform on rail components such as clamps, supports, plates, and the like, which are understood to be part of the rail. For example, in FIG. 2, a reference to a rail can refer to the rail R and the components Ra, Ra′.

Referring to FIG. 2, the transport device 100 may move along the rail R and transport a wafer carrier 170. For example, the rail R may be installed on the ceiling of a clean room in which process equipment is placed, and the transport device 100 may move over the process equipment.

The rail R may be placed adjacent to process equipment installed in a semiconductor production line or clean room, and the rail R may extend in one direction. The transport device 100 may transport wafers loaded on the wafer carrier 170 to a load port positioned adjacent to the process equipment.

The transport device 100 may include a driving unit 110, a steering wheel 120, the housing 130, a moving unit 140, an elevating unit 150, and a holding unit 160. The driving unit 110 and the steering wheel 120 may be placed on the rail R, and the driving unit 110 may travel horizontally along the rail R while in contact with the rail R. The steering wheel 120 may be placed on a side of the driving unit 110 and by supported by the rail R. The steering wheel 120 may rotate on the rail R to move the driving unit 110. For example, an actuator installed inside the driving unit 110 may rotate the steering wheel 120.

The housing 130, the moving unit 140, the elevating unit 150, and the holding unit 160 may be placed under the rail R. The housing 130 may be placed under the driving unit 110 and fixed to the driving unit 110. One or more side surfaces and/or the bottom surface of the housing 130 may be opened.

The moving unit 140, the elevating unit 150, and the holding unit 160 may be placed inside the housing 130. The moving unit 140 may be placed on the inner top surface of the housing 130. The moving unit 140 may move horizontally through an open side surface of the housing 130. The elevating unit 150 is positioned below the moving unit 140 and may be fixed to the moving unit 140. The holding unit 160 is placed below the elevating unit 150 and may be connected to the elevating unit 150 through an elevating mechanism such as a belt, an arm, or a bar. The holding unit 160 may hold the wafer carrier 170 and be moved up and down by the elevating unit 150.

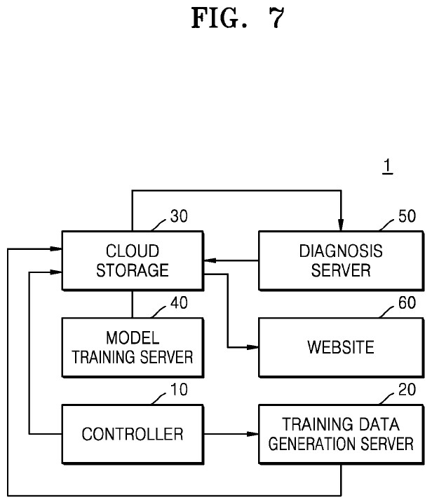

Referring to FIGS. 1 and 3, a diagnosis method may generate training data by processing video data captured by an OHT device (operation S200). First, video data may be collected (operation S220) according to a training data generation command (operation S210). In some implementations, video data captured by the OHT device is stored in a controller (10, refer to FIG. 7), and a training data generation server (20, refer to FIG. 7) may collect the video data by connecting to the controller by using a file transfer protocol (FTP). Hereinafter, video data collected for generating training data is referred to as first video data VD1.

Images may be extracted from the first video data VD1 (operation S230). First image data ID1 may be extracted from the first video data VD1 at a pre-set frames-per-second (FPS) value (e.g., 1 FPS). In some implementations, the first image data ID1 may be classified into training data, validation data, and test data. The training data is video data used to train a diagnosis model, the validation data is video data used for verification at each stage of training, and the test data is video data used for final inspection of the diagnosis model after training is complete.

Referring to FIG. 3, augmentation may be performed on the first image data ID1 to obtain augmented image data AID. The augmented image data AID may include data in which at least a portion of the first image data ID1 is rotated, color changed, cropped, and/or noise-added. The operation S200 of generating training data in some implementations may improve the performance of a diagnosis model by generating training data by supplementing image data regarding defective components, which may be insufficient in a manufacturing line, through augmentation of the first image data ID1.

In some implementations, training data may be generated depending on the type of deep learning-based diagnosis model to be trained using the training data. For example, the diagnosis model may be based on at least one of various suitable algorithms for object detection and image segmentation. Object detection and image segmentation are techniques used to analyze images. Object detection includes a task of finding a particular object in an image or a video and marking the location of the particular object with a bounding box, and image segmentation includes a task of dividing an image into pixels and assigning a particular class label to each pixel.

Referring to FIG. 3, a labeling task may be selected depending on whether a diagnosis model to be trained is a model based on an object detection algorithm (operation S250). When the diagnosis model to be trained is a model based on an object detection algorithm (YES), a labeling program for object detection may be executed (operation S261) to generate training data T1 (Detection Labels). When the diagnosis model to be trained is not a model based on an object detection algorithm (NO) (e.g., when the diagnosis model is a model based on an image segmentation algorithm), a labeling program for image segmentation may be executed (operation S262) to generate training data T2 (Segmentation Label). Afterwards, generation of training data may be terminated (operation S270).

Referring to FIG. 1, the diagnosis method may include training a diagnosis model based on training data T1 and T2 described above with reference to FIG. 3 (operation S300). In some implementations, the training data T1 and T2 is uploaded to a cloud storage (30, refer to FIG. 7), and an operation of training the diagnosis model may be performed on a model training server (40, refer to FIG. 7) as the diagnosis model obtains training data from the cloud storage. In some implementations, only one of T1 or T2 is used for training.

Referring to FIGS. 1 and 4, the state of a rail (R, refer to FIG. 2) may be inferred through a diagnosis model M (operation S400). The rail whose state is inferred may be the same as or different from the rail of which video data was captured to generate the training data. The inference of the state of the rail R may be understood as detecting a defective component Ra′ from among the components Ra of the rail R. The presence/absence, the detected location, and/or the detected time of a defective component Ra′ may be obtained through the diagnosis model M.

The diagnosis model M may infer the state of the rail R based on video data. The video data may be a video captured by the camera C of the transport device 100 moving along the rail R. The video data may be stored in a controller 10. Hereinafter, video data used for inference of the diagnosis model M is referred to as second video data VD2. The second video data VD2 may be input to the diagnosis model M. In some implementations, the diagnosis model M may include failure detection models for various components Ra. For example, the diagnosis model M may include a clamp failure detection model M1, a plate failure detection model M2, and a support failure detection model M3. The clamp failure detection model M1, the plate failure detection model M2, and the support failure detection model M3 may output inference results IR including results of detecting a defective clamp, a defective plate, and a defective support, respectively, based on the second video data VD2. The inference results IR may include inference results IR of the diagnosis model M for image data (hereinafter, “second image data”) extracted from the second video data VD2 at a pre-set FPS value (e.g., 1 FPS).

In some implementations, operation S400 of inferring the state of the rail R through the diagnosis model M may be performed in any one of three modes: long run, manual, and auto. A long run mode enables setting of a long run schedule per bay (or work area) in advance and analysis of a desired bay in detail. A manual mode enables analysis by moving the transport device 100 to a desired area to be explored without a prior schedule. An auto mode enables automatic analysis of video data captured by the transport device 100 moving according to pre-set cycle and time.

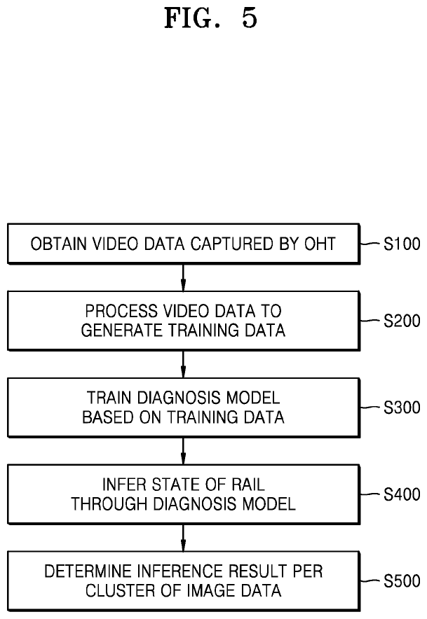

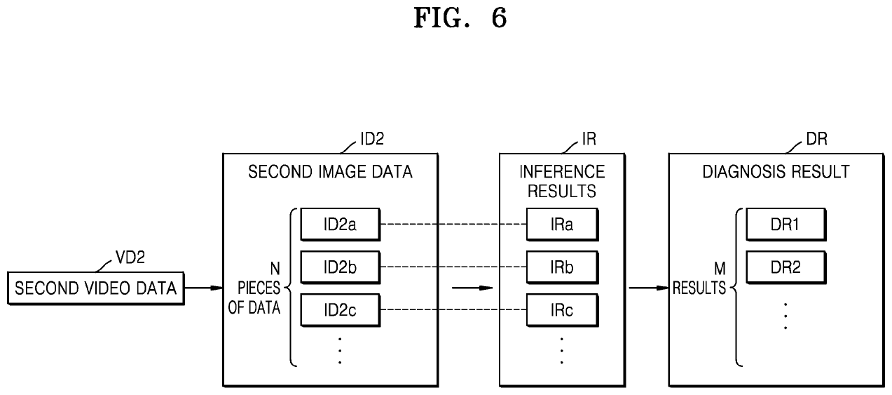

FIG. 5 is a schematic flowchart of an example of a diagnosis method, and FIG. 6 is a block diagram illustrating an example of an operation of determining a diagnosis result included in the diagnosis method.

Referring to FIGS. 5 and 6, a diagnosis method (e.g., the diagnosis method of FIG. 1) may further include operation S500 of determining a diagnosis result for each cluster of video data. As described above, the inference results IR of the diagnosis model M may include an inference result for the second image data ID2 extracted from the second video data VD2 at a certain FPS value. For example, when n pieces of second image data ID2 are extracted from the second video data VD2, the inference results IR of the diagnosis model M therefore may also be n pieces. In other words, the diagnosis model M may output inference results IRa, IRb, IRc, and so on of determining whether each of second video data ID2a, ID2b, ID2c, and so on includes a defective component Ra′.

Thereafter, the second image data ID2 from which the inference results IR are obtained may be clustered, and a diagnosis result DR may be determined for each of the clusters of the second image data ID2. Therefore, m diagnosis results DR may be extracted, wherein m is less than the number n of inference results IR. The second image data ID2 may be extracted from the video on a frame-by-frame basis, and the clustering may be performed by grouping consecutively captured frames at predetermined time intervals. By configuring temporally adjacent frames into a single cluster in this manner, variations caused by local noise, momentary changes in illumination, shaking, or the like among images continuously capturing the same rail section may be mitigated. Accordingly, by determining the diagnosis result DR based on representative characteristics of each cluster, the reliability and accuracy of defect detection may be improved compared to determinations based on individual frames.

In some implementations, the diagnosis result DR for each cluster may be determined based on an inference ratio of the inference results IR corresponding to the second image data ID2 included in the cluster. For example, when the n pieces of second image data ID2 are clustered by every k pieces (k<n), and a ratio between inference results inferred as defective and k inference results IR corresponding to k second image data ID2 per cluster is equal to or greater than a certain ratio, a diagnosis result DR regarding a corresponding cluster may be determined as defective. That is, when the n pieces of second image data ID2 are clustered into a cluster including k pieces (k<n), and a ratio between (i) inference results inferred IR as defective from within the k inference results of the cluster and (ii) k (that is, the total number of inference results of the cluster) is equal to or greater than a certain ratio, a diagnosis result DR corresponding to the cluster may be determined as defective. In some implementations, the second image data ID2 may be clustered in the time order in the second video data VD2.

FIG. 7 is a block diagram illustrating an example of a diagnosis system. Referring to FIG. 7, a diagnosis system 1 may include the controller 10, the training data generation server 20, the cloud storage 30, the model training server 40, a diagnosis server 50, and a website 60. At least a portion of the diagnosis system 1 may perform at least a portion of the diagnosis methods described above with reference to FIGS. 1 to 7.

Referring to FIGS. 1 to 7, the controller 10 may store, in real time, video data captured by the camera C of the transport device 100 of an OHT device while moving on the rail R. The video data may be a video taken of the upper portion of the rail R. The video data may be a video taken of the components Ra of the rail R. According to some implementations, the video data may be a video taken of the lower portion of the rail R. The video data may include the first video data VD1 used for training the diagnosis model M and the second video data VD2 that is a diagnosis target of the diagnosis model M.

The training data generation server 20 may generate the training data T1 and T2. The training data generation server 20 may obtain first video data VD1 from the controller 10 and process the first video data VD1 into data (training data) that may be used for training. The training data is data used to train a deep learning model, and the data structure thereof may depend on the structure of the deep learning model and a training algorithm. The diagnosis model M in some implementations may include an object detection algorithm or an image segmentation algorithm, and the training data generation server 20 may generate the training data T1 and T2 through a labeling program for object detection or image segmentation.

The training data generation server 20 may extract the first video data VD1 collected from the controller 10 as the first image data ID1 at a pre-set FPS value. In some implementations, the training data generation server 20 may extract the first video data VD1 as the first image data ID1 at 1 FPS. The training data generation server 20 may perform augmentation on the first image data ID1. The augmentation of the first image data ID1 may include data in which at least a portion of the first image data ID1 is rotated, color changed, cropped, or noise-added.

The first image data ID1 or the augmented image data AID may be stored in the cloud storage 30. For example, the cloud storage 30 may store the first image data ID1 or the augmented image data AID. The cloud storage 30 may store the first image data ID1 or the augmented image data AID by classifying them into training data, validation data, and test data.

The model training server 40 may train a deep learning-based diagnosis model M based on the training data T1 and T2. The model training server 40 may be a server realized through a docker image that includes dependencies needed for training and developing a model. Computing resources, libraries, source codes, etc. needed by the diagnosis model M may be defined in the docker image. The model training server 40 may obtain the training data T1 and T2 from the cloud storage 30 and train the diagnosis model M. In some implementations, weights obtained by completing training and testing in the model training server 40 may be stored in the cloud storage 30.

The cloud storage 30 may store the second video data VD2 from among video data stored in the controller 10. The second video data VD2 may be video data that is the target to be diagnosed by the diagnosis model M, e.g., video data of a target rail to be analyzed.

The diagnosis server 50 may infer the status of the rail R (that is, a rail of which training data was captured, or a different rail) based on the diagnosis model M. The diagnosis server 50 may obtain the second video data VD2 from the cloud storage 30. In some implementations, the diagnosis server 50 may directly connect to the controller 10 to obtain the second video data VD2 and then store the second video data VD2 in the cloud storage 30.

In some implementations, the diagnosis server 50 may include three modes (long run, manual, and auto). A long run mode enables setting of a long run schedule per bay (or work area) in advance and analysis of a desired bay in detail. A manual mode enables analysis by moving the transport device 100 to a desired area to be explored without a prior schedule. An auto mode enables automatic analysis of video data captured by the transport device 100 moving according to pre-set cycle and time.

The diagnosis server 50 may extract the second image data ID2 from the second video data VD2 at a pre-set FPS value (e.g., 1 FPS) and extract the inference results IR for the second image data ID2. The diagnosis server 50 may extract the inference results IR by operating the diagnosis model M for each detection item. For example, the diagnosis model M includes the clamp failure detection model M1, the plate failure detection model M2, and the support failure detection model M3, and the diagnosis server 50 may operate each of the clamp failure detection model M1, the plate failure detection model M2, and the support failure detection model M3 to extract the inference results IR.

The diagnosis server 50 may cluster the second image data ID2 and determine the diagnosis result DR for each cluster of the second image data ID2. In some implementations, the diagnosis result DR may be determined based on an inference ratio of the inference results IR corresponding to the second image data ID2 included in a cluster. The diagnosis result DR is stored in the cloud storage 30, and the diagnosis server 50 may delete the second video data VD2 after inference and/or diagnosis is completed.

In some implementations, the diagnosis result DR stored in the cloud storage 30 may be linked to the website 60. Users may access the website 60 to check the diagnosis result DR. The diagnosis result DR may include whether a defective component is detected for the second image data ID2. The diagnosis result DR may include a location and a time corresponding to the second image data ID2 where a defective component was detected.

The cloud storage 30 may further include an original data storage that stores video data captured by the camera of the transport device 100, a diagnosis result storage that stores inference results and/or diagnosis results of the diagnosis model M, a training data storage that stores training data, as well as, in some implementations, a user manual data storage and a history storage. Therefore, a diagnosis system with improved convenience may be provided by utilizing or including the cloud storage 30 that may be flexibly expanded according to the size of data, and which has excellent accessibility in a cloud environment.

Referring to FIGS. 1 to 7, the described diagnosis methods and systems may reduce the risk and the time elapsed for inspection of the rail R due to high-altitude work by inferring the state of the rail R (e.g., whether the components Ra of the rail R are defective) based on video data VD1 and VD2 obtained while the transport device 100 moves along the rail R and the deep learning-based diagnosis model M. Also, uneven inspection quality between workers may be improved. In addition, the described diagnosis methods and systems may ensure diversity (photographing the same object or similar objects in various ways) and integrity (photographing accurately without missing the object) of data by utilizing image data extracted from video data when generating training data and making inferences through a diagnosis model. Moreover, the described diagnosis methods and systems may make a diagnosis model more robust by supplementing insufficient training data by performing data augmentation when generating training data. The described diagnosis methods and systems may improve the accuracy of diagnosis by determining a diagnosis result for each cluster of image data by considering an inference result for the image data.

At least some of the operations of the foregoing diagnosis methods may be performed by an electronic device including a memory and one or more processors.

The memory may store instructions that may be read by a computer. When instructions stored in the memory are executed by a processor, the processor may process operations defined by the instructions. The memory may include, for example, random access memories (RAMs), dynamic random access memories (DRAMs), static random access memories (SRAMs), or other forms of non-volatile memory known in the art.

One or more processors in some implementations may control the overall operation of an electronic device. A processor may be a hardware-implemented device having circuitry having a physical structure for executing desired operations. The desired operations may include code or instructions in a program. The hardware-implemented device may include a microprocessor, a central processing unit (CPU), a graphics processing unit (GPU), a processor core, a multi-core processor, a multi-processor, an application-specific integrated circuit (ASIC), a field programmable gate array (FPGA), a neural processing unit (NPU), etc.

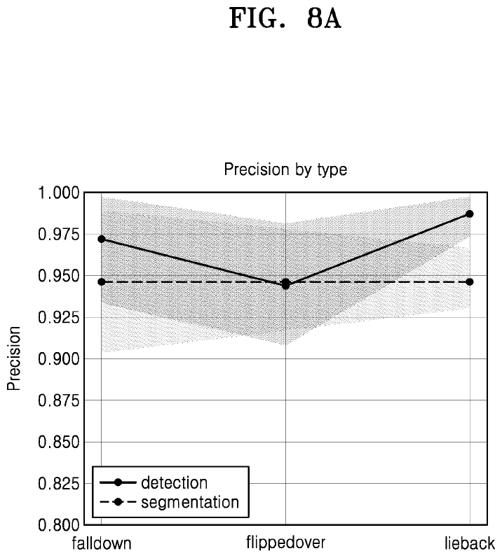

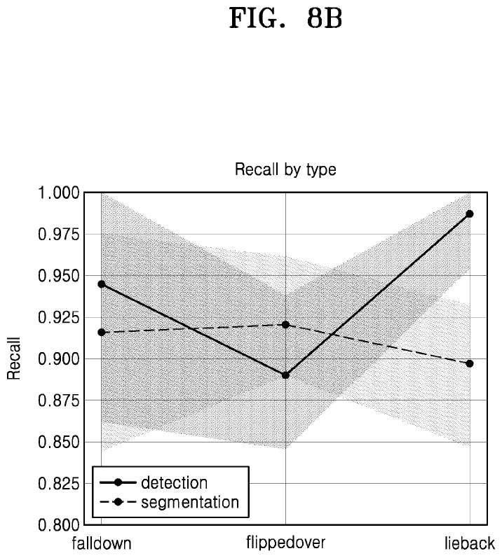

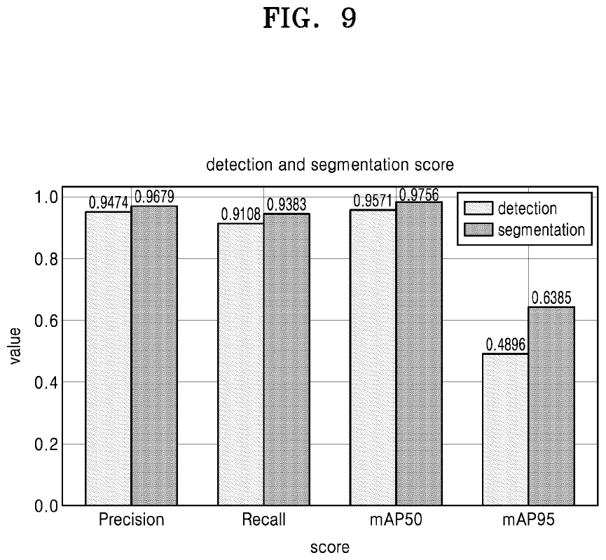

FIGS. 8A and 8B are graphs showing examples of performance of a diagnosis model. FIG. 9 is a graph showing an example of performance of a diagnosis model. A diagnosis model (e.g., M, refer to FIG. 4) in a diagnosis method and a diagnosis system, in any of the examples herein, may be based on at least one of an algorithm for object detection or an algorithm for image segmentation.

Since object detection may consider the surrounding area when distinguishing between a normal state and an abnormal state, the abnormal state of the components Ra may be detected by comparing the abnormal state of the components Ra with the shape of the rail R. Image segmentation may infer noise-robust and accurate detection areas by focusing on the normal state and the abnormal state of the components Ra.

FIGS. 8A and 8B are graphs showing the performance of a diagnosis model for detecting falldown, flipped-over, and lieback defects of a clamp from among components of a rail. Referring to FIG. 8A, a first diagnosis model (detection) based on object detection and a second diagnosis model (segmentation) based on image segmentation have precisions of 0.94 or higher for all defects. In other words, the first diagnosis model (detection) and the second diagnosis model (segmentation) each have a ratio of actual defects out of predicted defects of 0.94 or higher. Referring to FIG. 8B, the first diagnosis model (detection) based on object detection and the second diagnosis model (segmentation) based on image segmentation each show a recall rate of 0.88 or higher for all defects. In other words, the first diagnosis model (detection) and the second diagnosis model (segmentation) each have a ratio of predicted defects out of all actual defects of 0.88 or higher.

FIG. 9 shows performance values extracted through K-fold cross-validation with respect to the first diagnosis model (detection) based on object detection and the second diagnosis model (segmentation) based on image segmentation. Referring to FIG. 9, the second diagnosis model (segmentation) exhibits higher performance values in precision, recall, mAP50, and mAP95, respectively. Here, mAP (average precision) is an indicator for evaluating a model's performance and is a value that measures the harmony between precision and recall. mAP50 is an mAP value when an intersection over union (IoU) threshold is fixed to 0.5 (50%), and mAP95 is the average of mAP calculated by changing the IoU threshold from 0.5 to 0.95 at the interval of 0.05.

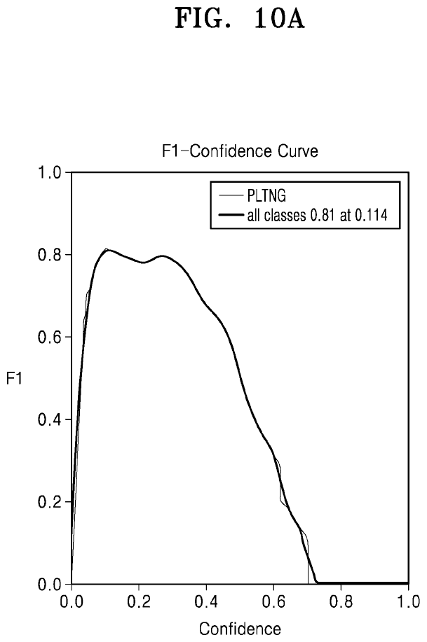

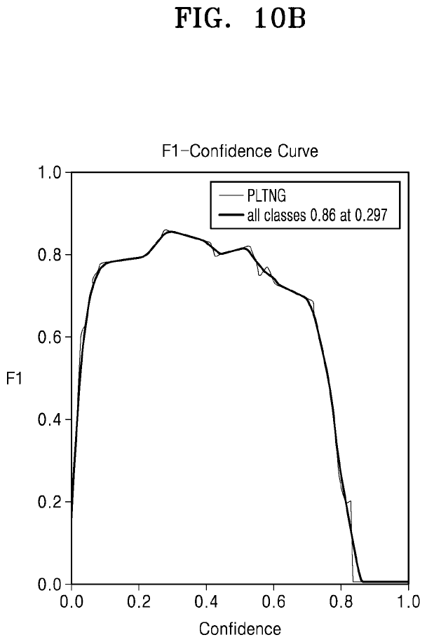

FIGS. 10A and 10B are graphs illustrating an example of an effect of augmenting training data. As described above with reference to FIGS. 3 and 7, when bad data (that is, training data showing a defective component) is insufficient and/or insufficiently diverse, augmentation may be performed to supplement training data. FIG. 10A shows an F1-Confidence curve of a diagnosis model trained with training data on which augmentation is not performed, and FIG. 10B shows an F1-Confidence curve of a diagnosis model trained with training data on which augmentation is performed.

Referring to FIG. 10A, the diagnosis model trained with training data without augmentation has an F1 score of 0.81 at a confidence threshold of 0.114. In contrast, referring to FIG. 10B, the diagnosis model trained with training data on which augmentation is performed has an F1 score of 0.86 at a confidence threshold of 0.297. In other words, since a diagnosis model trained with training data on which augmentation is performed has a higher F1 score than the F1 score of the diagnosis model trained with training data without augmentation, the diagnosis model trained with training data on which augmentation is performed may have better performance. Here, the F1 score is the harmonic mean of precision and recall.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While certain examples have been particularly shown and described, it will be understood that various changes in form and details may be made therein without departing from the spirit and scope of this disclosure.

What is claimed is:

1. A diagnosis method comprising:
obtaining first video data of a first rail of an overhead hoist transport (OHT) system, wherein the first video data is captured by a transport device of the OHT system while the transport device is on the first rail;
generating training data based on the first video data;
training a deep learning-based diagnosis model based on the training data;
providing second video data of the first rail or a second rail as input to the deep learning-based diagnosis model; and
obtaining, as an output of the deep learning-based diagnosis model based on the second video data, an inference result indicative of a presence of a defective component of the first rail or of the second rail.

2. The diagnosis method of claim 1, wherein generating the training data comprises extracting image data from the first video data at a predetermined frames-per-second value.

3. The diagnosis method of claim 2, wherein generating the training data comprises performing augmentation on the image data, and
wherein performing the augmentation comprises generating augmented image data by performing at least one of rotating, color changing, cropping, or noise-addition on at least a portion of the image data.

4. The diagnosis method of claim 1, wherein the deep learning-based diagnosis model comprises at least one of an object detection algorithm or an image segmentation algorithm.

5. The diagnosis method of claim 1, comprising:
uploading the second video data to a cloud storage; and
obtaining, by a diagnosis server, the second video data from the cloud storage,
wherein the deep learning-based diagnosis model is configured to obtain the inference result.

6. The diagnosis method of claim 1, comprising uploading the training data to a cloud storage,
wherein training the deep learning-based diagnosis model comprises obtaining, by a model training server, the training data from the cloud storage.

7. The diagnosis method of claim 1, wherein providing the second video data as input to the deep learning-based diagnosis model comprises:
extracting a plurality of images from the second video data at a predetermined frames-per-second value; and
performing inference on the plurality of images using the deep learning-based diagnosis model.

8. The diagnosis method of claim 7, wherein performing the inference comprises:
clustering the plurality of images into a plurality of clusters; and
determining a respective diagnosis result indicative of a state of the first rail or of the second rail for each of the plurality of clusters.

9. The diagnosis method of claim 8, wherein determining the respective diagnosis result for each cluster of the plurality of clusters is based on an inference ratio of inference results of image data included in the cluster.

10. The diagnosis method of claim 1, comprising:
moving the transport device or a second transport device along the first rail or the second rail; and
while the transport device or the second transport device is moving along the first rail or the second rail, capturing the second video data.

11. The diagnosis method of claim 10, wherein the second video data includes video data of an upper portion of the first rail or of the second rail.

12. The diagnosis method of claim 1, wherein the deep learning-based diagnosis model comprises:
a first model configured to detect one of a clamp failure, a plate failure, or a support failure detection model; and
a second model, distinct from the first model, configured to detect another of the clamp failure, the plate failure, or the support failure detection model.

13. A diagnosis system comprising:
a controller configured to store video data of a first rail of an overhead hoist transport (OHT) system, wherein the video data is captured by a transport device of the OHT system while the transport device is on the first rail;
a training data generation server configured to generate training data based on the video data;
a cloud storage configured to store the training data generated by the training data generation server;
a model training server configured to train a deep learning-based diagnosis model based on the training data; and
a diagnosis server configured to infer a presence of a defective component of the first rail or of a second rail using the deep learning-based diagnosis model.

14. The diagnosis system of claim 13,
wherein the cloud storage is configured to store second video data of the first rail or of the second rail, and
wherein the diagnosis server is configured to:
obtain the second video data from the cloud storage, and
infer the presence of the defective component based on the second video data.

15. The diagnosis system of claim 14, wherein the diagnosis server is configured to:
extract a plurality of images from the second video data at a predetermined frames-per-second value; and
infer the presence of the defective component based on the plurality of images.

16. The diagnosis system of claim 15, wherein the diagnosis server is configured to:
cluster the plurality of images into a plurality of clusters; and
determine a respective diagnosis result indicative of a state of the first rail or of the second rail for each of the plurality of clusters.

17. The diagnosis system of claim 16, wherein the cloud storage is configured to store a diagnosis result indicating the presence of the defective component.

18. The diagnosis system of claim 13, wherein the training data generation server is configured to generate the training data by extracting first image data from the video data at a predetermined frames-per-second value.

19. The diagnosis system of claim 18, wherein the training data generation server is configured to perform augmentation on the first image data to generate additional training data.

20. A diagnosis method comprising:
obtaining first video data captured by a camera while the camera moves along a first rail of an overhead hoist transport (OHT) system;
extracting first image data from the first video data;
generating augmented image data by performing augmentation on the first image data;
training a deep learning-based diagnosis model based on the augmented image data;
obtaining second video data of the first rail or of a second rail;
extracting second image data from the second video data;
clustering the second image data into a plurality of clusters; and
for each of the plurality of clusters, obtaining, using the deep learning-based diagnosis model, an inference of whether the first rail or the second rail is abnormal based on the second image data in the cluster,
wherein the deep learning-based diagnosis model comprises at least one of an object detection model or an image segmentation model.
